(19) United States
(12) Patent Application Publication
(10) Pub. No.: US 2024/0272544 A1
(43) Pub. Date: Aug. 15, 2024

(54) METHOD OF MANUFACTURING A PHOTOMASK

(71) Applicant: Samsung Electronics Co., Ltd., Suwon-si (KR)

(72) Inventors: Hyoyeon KIM, Suwon-si (KR); Sukjong BAE, Suwon-si (KR); Kangho PARK, Suwon-si (KR); Yuri KIM, Suwon-si (KR)

(73) Assignee: Samsung Electronics Co., Ltd., Suwon-si (KR)

(21) Appl. No.: 18/417,718

(22) Filed: Jan. 19, 2024

(30) Foreign Application Priority Data
Feb. 9, 2023 (KR) 10-2023-0017433

(51) Int. Cl. G03F 1/70

(52) U.S. Cl. CPC G03F 1/70

(57) ABSTRACT

In a method of manufacturing a photomask, a layout of a target pattern to be formed in the photomask may be designed. A modeling of a displacement error of the target pattern may be performed and a displacement error correction map of the target pattern may be generated based on the modeling of the displacement error of the target pattern. An exposure process may be performed on a blank mask in reflection of the displacement error correction map of the target pattern. A developing process and an etching process may be performed on the blank mask to form the photomask.

### CROSS-REFERENCE TO RELATED APPLICATION

This application claims priority under 35 U.S.C. § 119 to Korean Patent Application No. 10-2023-0017433, filed on Feb. 9, 2023 in the Korean Intellectual Property Office, the disclosure of which is hereby incorporated by reference in its entirety.

### TECHNICAL FIELD

Example embodiments of the present disclosure relate to a method of manufacturing a photomask.

### DISCUSSION OF RELATED ART

When a layout of a target pattern having a desired shape is designed, an OPC may be performed on the layout of the target pattern to correct the layout of the target pattern, and a photomask may be manufactured based on the corrected layout of the target pattern. However, there may be a displacement error between the target pattern and a real pattern formed in the photomask, and thus a correction may be needed for displacement error.

### SUMMARY

Example embodiments provide an enhanced method of manufacturing a photomask.

According to example embodiments of inventive concepts, a method of manufacturing a photomask may include designing a layout of a target pattern to be formed in the photomask; performing a modeling of a displacement error of the target pattern and generating a displacement error correction map of the target pattern, based on the modeling of the displacement error; performing an exposure process on a blank mask in reflection of the displacement error correction map of the target pattern; and performing a developing process and an etching process on the blank mask to form the photomask.

According to example embodiments of inventive concepts, a method of manufacturing a photomask may include designing a layout of a target pattern to be formed in the photomask; performing a modeling of a displacement error of the target pattern and generating a displacement error correction map of the target pattern, based on the modeling of the displacement error; correcting the layout of the target pattern by reflecting the displacement error correction map of the target pattern to provide a corrected layout of the target pattern; performing an exposure process on a blank mask according to the corrected layout of the target pattern; and performing a developing process and an etching process on the blank mask to form the photomask.

According to example embodiments of inventive concepts, a method of manufacturing a photomask may include designing a layout of a target pattern to be formed in the photomask; performing a laser annealing process on a portion of a blank mask to form a border region; performing a modeling of a displacement error of the target pattern and generating a displacement error correction map of the target pattern, based on the modeling of the displacement error; performing an exposure process on the blank mask in reflection of the displacement error correction map of the target pattern; and performing a developing process and an etching process on the blank mask to form the photomask.

According to example embodiments of inventive concepts, a method of manufacturing a photomask may include designing a layout of a target pattern to be formed in the photomask; performing a laser annealing process on a portion of a blank mask to form a border region; performing a modeling of a displacement error of the target pattern and generating a displacement error correction map of the target pattern, based on the modeling of the displacement error; correcting the layout of the target pattern by reflecting the displacement error correction map of the target pattern to provide a corrected layout of the target pattern; performing an exposure process on the blank mask according to the corrected layout of the target pattern; and performing a developing process and an etching process on the blank mask to form the photomask.

According to example embodiments of inventive concepts, a method of manufacturing a photomask may include designing a layout of a target pattern to be formed in the photomask; performing an etching process on a portion of a blank mask to form a border region; performing a modeling of a displacement error of the target pattern and generating a displacement error correction map of the target pattern, based on the modeling of the displacement error; performing an exposure process on the blank mask in reflection of the displacement error correction map of the target pattern; performing a developing process and a first etching process on the blank mask to form the photomask; and performing a second etching process on a portion of the photomask to form a border region in the photomask.

According to example embodiments of inventive concepts, a method of manufacturing a photomask may include designing a layout of a target pattern to be formed in the photomask; performing an etching process on a portion of a blank mask to form a border region; performing a modeling of a displacement error of the target pattern and generating a displacement error correction map of the target pattern, based on the modeling of the displacement error; correcting the layout of the target pattern by reflecting the displacement error correction map of the target pattern to provide a corrected layout of the target pattern; performing an exposure process on the blank mask according to the corrected layout of the target pattern; performing a developing process and a first etching process on the blank mask to form the photomask; and performing a second etching process on a portion of the photomask to form a border region in the photomask.

In a method of manufacturing the photomask according to an example embodiment, the modeling of the displacement error of the target pattern may be performed based on the pattern displacement error data of the patterns having the same or similar layouts to the layout of the target pattern included in the previously-manufactured photomasks, the displacement error correction map of the target pattern may be generated, and the photomask may be manufactured in reflection of the displacement error correction map of the target pattern.

Thus, the error between the position of the real pattern formed in the photomask and the position of the target pattern in the initially designed photomask may be corrected, so that the photomask may include the real pattern having a layout very close to the layout of the target pattern. Additionally, an overlay error modeling may be performed based on in-shot overlay data of a wafer, a displacement error correction map of the target pattern that may correct the position of the target pattern be generated based on the overlay error modeling may be generated, and a photomask may be generated in reflection of the generated displacement error correction map of the target pattern. Accordingly, the photomask that may contribute the enhancement of the quality of the wafer overlay may be manufactured.

### BRIEF DESCRIPTION OF THE DRAWINGS

FIG. 1 is a schematic cross-sectional view illustrating a photolithography system in accordance with example embodiments.

FIG. 2 is a cross-sectional view illustrating the photomask M in accordance with example embodiments.

FIGS. 3 and 4 are a plan view and a cross-sectional view illustrating the photomask M in accordance with example embodiments.

FIGS. 5 and 6 are a plan view and a cross-sectional view illustrating the photomask M in accordance with example embodiments.

FIGS. 7 and 8 are plan views illustrating areas of the wafer WF onto which lights reflected from photomasks are projected during exposure processes using the photomasks in accordance with example embodiments.

FIG. 9 is a flowchart illustrating a method of correcting a displacement error of a pattern of a photomask and a method of manufacturing a photomask in accordance with example embodiments.

FIG. 10 is a density map of target patterns included in a designed photomask in accordance with example embodiments, and FIG. 11 is a convolution map of position data of the target patterns included in the photomask of FIG. 10 and displacement error data of patterns included in the previously-manufactured photomasks in which the density of the patterns is the same as, substantially the same as, or similar to that of the designed photomask.

FIG. 12 is a displacement error correction map of the target pattern generated based on the convolution map shown in FIG. 11, FIG. 13A is drawing that shows a displacement error of a real pattern included in the photomask before reflecting the displacement error correction map of the target pattern in an exposure process, and FIG. 13B is drawing that shows a displacement error of the real pattern included in the photomask after reflecting the displacement error correction map of the target pattern in the exposure process.

FIG. 14 is a flowchart illustrating a method of correcting a pattern displacement error and a method of manufacturing a photomask in accordance with example embodiments.

FIG. 15 is a flowchart illustrating a method of correcting a pattern displacement error and a method of manufacturing a photomask in accordance with example embodiments.

FIG. 16 is an image of four corners of a region where the MLA process is performed in the blank mask.

FIG. 17 is a drawing illustrating the modeling of the pattern displacement error performed based on the pattern displacement error of the previously-manufactured photomasks at a region close to first and fourth points P1 and P4 that are located in a region where the MLA process is performed in FIG. 16.

FIGS. 18 and 19 are displacement error correction maps of the target pattern generated based on the modeling of the pattern displacement error in FIG. 17.

FIGS. 20 and 21 are drawings showing displacement errors of real patterns in the photomasks, respectively, that are manufactured by reflecting the pattern displacement error correction maps shown in FIGS. 18 and 19, respectively.

FIG. 22 is a flowchart illustrating a method of correcting a pattern displacement error of a photomask and a method of manufacturing a photomask in accordance with example embodiments.

FIG. 23 is a flowchart illustrating a method of correcting a pattern displacement error of a photomask and a method of manufacturing a photomask in accordance with example embodiments.

FIG. 24 is drawings illustrating the modeling of pattern displacement error based on the pattern displacement error of the previously-manufactured photomasks in a region where the MLE process is performed.

FIG. 25 is a displacement error correction map of the target pattern generated based on the modeling of the pattern displacement error shown in FIG. 24.

FIG. 26 is a drawing showing the pattern displacement error of the photomask.

FIG. 27 is a flowchart illustrating a method of correcting a pattern displacement error of a photomask and a method of manufacturing a photomask in accordance with example embodiments.

### DETAILED DESCRIPTION

The above and other aspects and features of a method of correcting a displacement error of a photomask, a method of manufacturing a photomask, and a method of manufacturing a semiconductor device using the same in accordance with example embodiments will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Patterns on a wafer may be formed by forming an etching object layer on the wafer, forming a photoresist layer on the etching object layer, patterning the photoresist layer to form a photoresist pattern, and etching the etching object layer using the photoresist pattern as an etching mask. An etching mask layer may be further formed between the etching object layer and the photoresist layer, and in this case, the etching mask layer may be etched using the photoresist pattern to form an etching mask, and the etching object layer may be etched using the etching mask.

The formation of the photoresist pattern by patterning the photoresist layer may be performed by placing a photomask, e.g., a reticle on which a given pattern having a layout is formed over the photoresist layer, performing an exposure process in which a light is emitted from a light source to penetrate through the photomask, and performing a developing process in which a portion of the photoresist layer exposed or unexposed by the light is removed, so that the layout of the given pattern may be transferred to the photoresist layer.

A deep ultraviolet (DUV) equipment using KrF or ArF as a light source has been mainly used, and recently an extreme ultraviolet (EUV) equipment has been used. By using the EUV equipment, patterns having a minute pitch or a curved shape may be easily formed.

Generally, a photolithography process in which a pattern having a desired layout is formed on a wafer using a photomask and a photoresist pattern may be performed using a photolithography system.

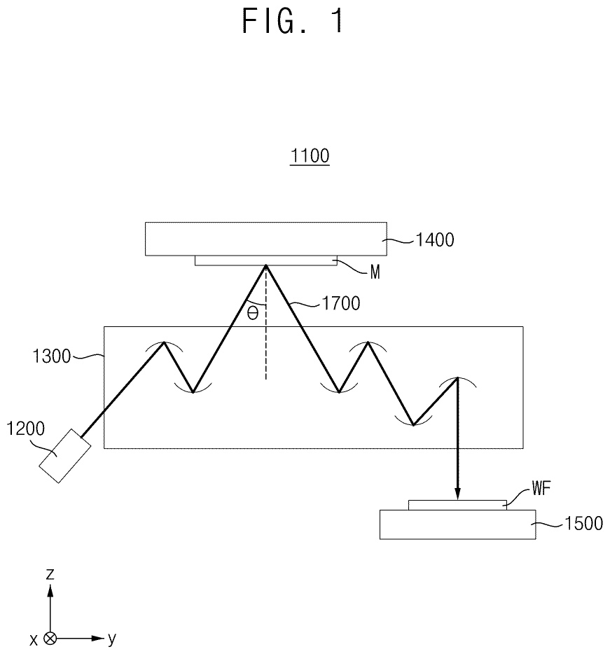

FIG. 1 is a schematic cross-sectional view illustrating a photolithography system in accordance with example embodiments.

Referring to FIG. 1, a photolithography system 1100 may include a light emitting part 1200, an optical system 1300, a mask stage 1400 and a wafer stage 1500, and the photolithography system 1100 may perform a photolithography process using a light 1700 and a photomask M.

Particularly, the light emitting part 1200 may include, e.g., a light source, a light collector, etc. The light source may generate the light 1700 using, e.g., a plasma source, a laser-induced source, an electric discharge gas plasma source, etc. In an example embodiment, the light 1700 may be an extreme ultraviolet (EUV) light having a wavelength of about 13.5 nm. Alternatively, the light 1700 may be a deep ultraviolet (DUV) light having a wavelength of about 193 nm. The light 1700 generated at the light source may pass through the light collector to be incident into the optical system 1300.

The optical system 1300 may include, e.g., mirrors, lenses, etc. In example embodiments, the optical system 1300 may include an illumination optical system and a projection optical system.

The illumination optical system may include optical elements e.g., illumination mirrors and/or illumination lenses in order to induce the light 1700 generated by the light source toward the photomask M that is installed on a lower surface of the mask stage 1400.

The mask stage 1400 may move in a horizontal direction, which may be parallel to an upper surface or the lower surface of the mask stage 1400, with the photomask M thereon. The horizontal direction may include two directions substantially perpendicular to each other, e.g., an x-direction and a y-direction, and the mask stage 1400 may move in the x-direction or y-direction. A direction substantially perpendicular to the upper surface or the lower surface of the mask stage 1400 may be referred to as a z-direction. A driving system (e.g., motor) (not shown) may be used to move the mask stage 1400.

The mask stage 400 may further include an electrostatic chuck for fixing the photomask M.

The light 1700 induced to the photomask M installed at the mask stage 1400 may be incident into the lower surface of the photomask M with an incident angle θ, and may be reflected to the projection optical system. The projection optical system may include optical elements, e.g., projection mirrors and/or projection lenses in order to induce the light 1700 reflected from the photomask M toward a wafer WF mounted on the wafer stage 1500.

The wafer stage 1500 may move in the horizontal direction with the wafer WF thereon. For example, a photoresist layer having a given thickness may be formed on the wafer WF, and a focus of the light 1700 induced toward the wafer WF mounted on the wafer stage 1500 may be located within the photoresist layer.

Thus, a photoresist pattern may be formed by an exposure process in which the light 1700 generated at the light source may be reflected on the photomask M to be illuminated on a photoresist layer on the wafer WF, and a developing process on the photoresist layer so that the photoresist layer may be patterned. An etching object layer under the photoresist pattern may be patterned based on the photoresist pattern so that a pattern having a desired layout may be formed on the wafer WF.

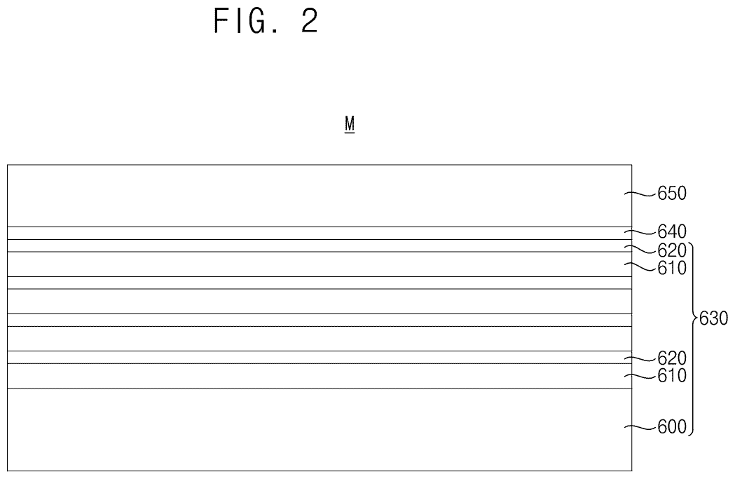

FIG. 2 is a cross-sectional view illustrating the photomask M in accordance with example embodiments.

Referring to FIG. 2 together with FIG. 1, the photomask M may include a multi-layered structure 630, a capping layer 640 and an absorber 650 sequentially stacked on a substrate 600. Additionally, the photomask M may further include a conductive layer between the mask stage 1400 and the substrate 600, and an anti-reflective layer on the absorber 650.

The substrate 600 may include a low thermal expansion material (LTEM), e.g., quartz glass, silicon, silicon carbide, etc. In an example embodiment, the substrate 600 may have a thickness of about several nanometers.

The multi-layered structure 630 may reflect the light 1700 incident onto the photomask M. The multi-layered structure 630 may include a first layer 610 and a second layer 620 alternately and repeatedly stacked in a vertical direction substantially perpendicular to an upper surface of the substrate 600. In example embodiments, the first and second layers 610 and 620 may include an amorphous silicon and molybdenum, respectively. Alternatively, the first and second layers 610 and 620 may include beryllium and molybdenum, respectively. The stack number or the stack order of the first and second layers 610 and 620 might not be limited to FIG. 2.

The multi-layered structure 630 may include the first and second layers 610 and 620 having different refractive indexes and alternately stacked in the vertical direction, and may reflect the light 1700 incident on the multi-layered structure 630. In an example embodiment, each of the first and second layers 610 and 620 may have a thickness of about several nanometers, and the multi-layered structure 630 may have a thickness of about dozens of nanometers to about hundreds of nanometers.

The capping layer 640 may be formed on an upper surface of the multi-layered structure 630, and may protect the multi-layered structure 630. In an example embodiment, the capping layer 640 may include ruthenium, and may have a thickness of about several nanometers.

The absorber 650 may include a material that may absorb the light 1700, e.g., tantalum, tantalum compound, etc. In example embodiments, the absorber 650 may include tantalum nitride. Alternatively, the absorber 650 may include tantalum boron nitride. The absorber 650 may have a thickness of about 50 nanometers to about 70 nanometers.

The lights 1700 generated at the light emitting part 1200 may be induced onto the photomask M with a slope angle θ. Some of the lights 1700 incident onto an area where the absorber 650 is formed may be absorbed by the absorber 650. Others of the lights 1700 incident onto an area where the absorber 650 is not formed may pass through the capping layer 640 to be reflected at an effective reflection surface of the multi-layered structure 630, and may move to the projection optical system of the optical system 1300 from the photomask M.

The absorber 650 of the photomask M may include a pattern having a given layout, and the lights 1700 reflected from the multi-layered structure 630 of the photomask M may be controlled according to the layout of the pattern so that the layout of the pattern may be transferred onto the wafer WF and that a pattern having a desired layout may be formed on the wafer WF.

As the lights 1700 are not in the vertical direction but slantly incident onto the upper surface of the photomask M, and thus not only some of the lights 1700 incident onto the area where the absorber 650 is formed but also some of the lights incident onto the area where the absorber 650 is not formed may be absorbed by the absorber 650 so that a mask 3-dimensional (3D) effect such as shadowing effect may occur.

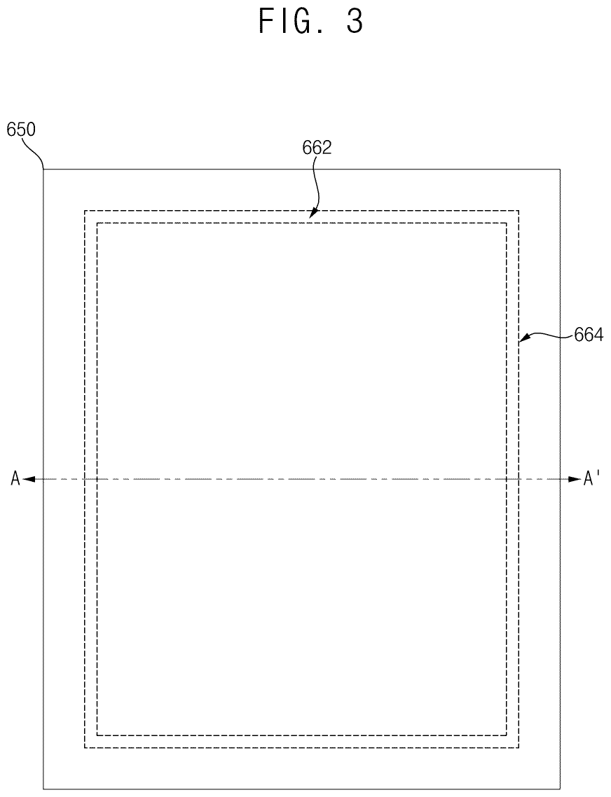

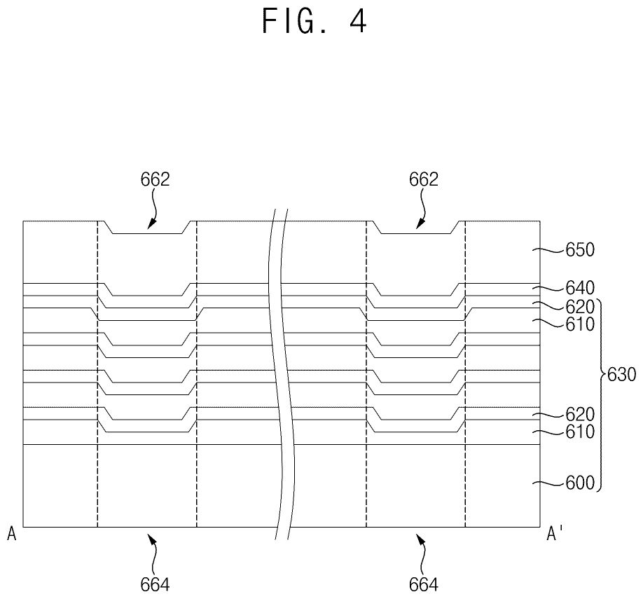

FIGS. 3 and 4 are a plan view and a cross-sectional view illustrating the photomask M in accordance with example embodiments. The photomask M shown in FIGS. 3 and 4 may be substantially the same as or similar to that of FIG. 2, except for further including a first border region, and thus repeated explanations are omitted herein.

Referring to FIGS. 3 and 4, the photomask M may include a first border region 664 at an edge portion thereof, and the first border region 664 may also be referred to as a first black border.

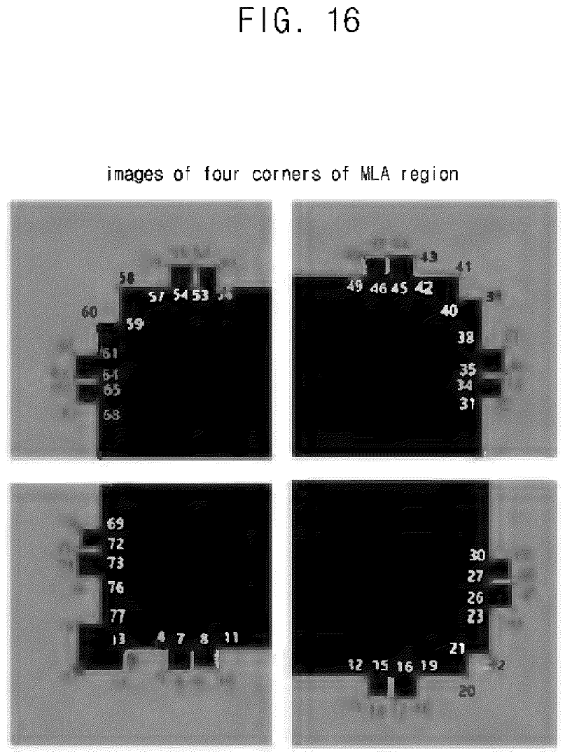

In example embodiments, the photomask M may have a shape of a rectangle in a plan view, and the first border region 664 may have a rectangular ring shape at the edge portion of the photomask M in a plan view. In an example embodiment, each of four corners of the rectangle ring shape may have concave and convex portions (refer to FIG. 16).

In example embodiments, the first border region 664 may be formed by a laser annealing process and the laser annealing process may include irradiating IR laser having a wavelength of about 980 nm onto an edge portion of the multi-layered structure 630 to crystallize a portion of the first layer 610 including, e.g., amorphous silicon.

As the portion of the first layer 610 at the edge portion of the multi-layered structure 630 onto which the IR laser is irradiated is crystallized, a thickness in the vertical direction of the portion of the first layer 610 may decrease by about 50 nm, and an upper surface of a portion of the second layer 620 on the portion of the first layer 610 may be lower than upper surfaces of other portions of the second layer 620. Thus, a thickness of the multi-layered structure 630 at the edge portion of the photomask M may decrease, and a recess 662 may be formed on an upper surface of a portion of the absorber 650 at the edge portion of the photomask M.

A portion of the photomask M having the recess 662 thereon may form the first border region 664, and a reflectivity of the first border region 664 may be lower than the reflectivity of other portions in the photomask M. Thus, most portion of the lights 1700 incident onto the first border region 664 may not be reflected outwardly, and an overlapping exposure due to the reflection of the lights 1700 into neighboring shots may be reduced or prevented during a photolithography process using the photomask M.

However, stress may be applied to the photomask M during the laser annealing process for forming the first border region 664, and thus positions of patterns included in the absorber 650 of the photomask M may be changed.

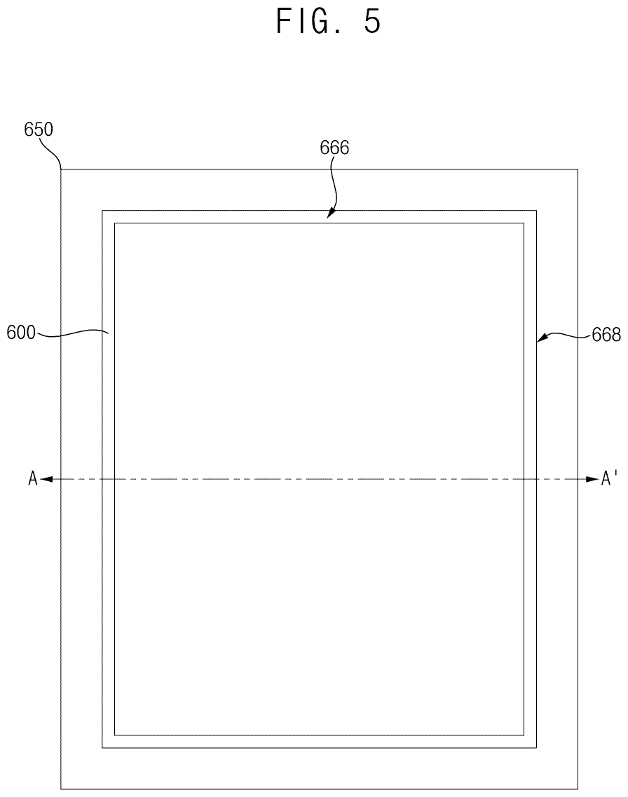

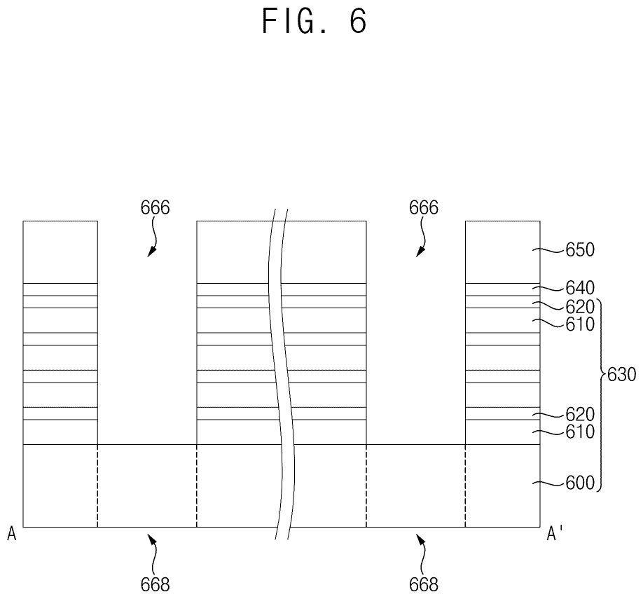

FIGS. 5 and 6 are a plan view and a cross-sectional view illustrating the photomask M in accordance with example embodiments. The photomask M shown in FIGS. 5 and 6 may be substantially the same as or similar to that of FIG. 2, except for further including a second border region, and thus repeated explanations are omitted herein.

Referring to FIGS. 5 and 6, the photomask M may include a second border region 668 at an edge portion thereof, and the second border region 668 may also be referred to as a second black border.

In example embodiments, the second border region 668 may have a rectangular ring shape at the edge portion of the photomask M in a plan view.

In example embodiments, the second border region 668 may be formed by performing, e.g., an etching process to form an opening 666 extending through portions of the multi-layered structure 630, the capping layer 640 and the absorber 650 at the edge portion of the photomask M and exposing an upper surface of the substrate 600.

A portion of the photomask M in which the opening 666 is formed may form the first second region 668, and a reflectivity of the second border region 668 may be lower than the reflectivity of other portions in the photomask M. Thus, most portion of the lights 1700 incident onto the second border region 668 may not be reflected outwardly, and an overlapping exposure due to the reflection of the lights 1700 into neighboring shots may be reduced or prevented during a photolithography process using the photomask M.

However, stress may be applied to the photomask M during the etching process for forming the second border region 668, and thus positions of patterns included in the absorber 650 of the photomask M may be changed.

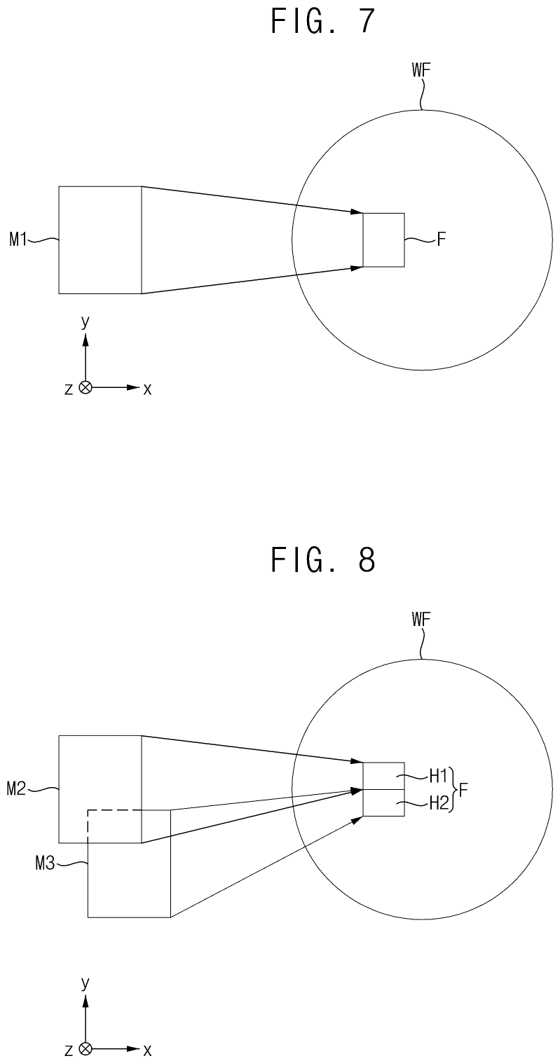

FIGS. 7 and 8 are plan views illustrating areas of the wafer WF onto which lights reflected from photomasks are projected during exposure processes using the photomasks in accordance with example embodiments.

Referring to FIG. 7 together with FIG. 1, the light 1700 generated at the light emitting part 1200 may be induced to a first photomask M1 on the lower surface of the mask stage 1400 by the illumination optical system of the optical system 1300 to be incident onto a lower surface of the first photomask M1 with the slope angle θ. The light 1700 reflected from the lower surface of the first photomask M1 may be induced onto the wafer WF mounted on the wafer stage 1500 by the projection optical system of the optical system 1300 to be incident on an upper surface of the wafer WF.

An area of the light 1700 incident on the upper surface of the wafer WF may decrease by a given ratio, that is, a reduction rate when compared to an area of the light 1700 incident on the lower surface of the first photomask M1. That is, the projection optical system may have a given reduction rate, and the projection optical system may be an isomorphic system including an isomorphic lens having the same reduction rate in the x-direction and the y-direction. For example, the projection optical system may have a reduction rate of about 4:1 in each of the x-direction and the y-direction.

An area of the wafer WF onto which a layout of a pattern included in the first photomask M1 is transferred by a first exposure process using the first photomask M1, that is, by one shot may be defined as a field F.

Referring to FIG. 8 together with FIG. 1, the light 1700 generated at the light emitting part 1200 may be induced to a second photomask M2 on the lower surface of the mask stage 1400 by the illumination optical system of the optical system 1300 to be incident onto a lower surface of the second photomask M2 with the slope angle θ. The light 1700 reflected from the lower surface of the second photomask M2 may be induced onto the wafer WF mounted on the wafer stage 1500 by the projection optical system of the optical system 1300 to be incident on the upper surface of the wafer WF.

An area of the light 1700 incident on the upper surface of the wafer WF may decrease by a given ratio, that is, a reduction rate when compared to an area of the light 1700 incident on the lower surface of the second photomask M2. That is, the projection optical system may have a given reduction rate, and the projection optical system may be an anamorphic system including an anamorphic lens having different reduction rates in the x-direction and the y-direction, respectively. For example, the projection optical system may have a reduction rate of about 4:1 in the x-direction a reduction rate of about 8:1 in the y-direction.

Thus, when a second exposure process is performed using the second photomask M2, a layout of a pattern included in the second photomask M2 may be transferred to a first half field H1 that may correspond to half the field F.

The second photomask M2 on the mask stage 1400 may be replaced with a third photomask M3 having the same size as the second photomask M2, the mask stage 1400 or the wafer stage 1500 may be moved in the y-direction, and a third exposure process may be performed using the third photomask M3, such that a layout of a pattern included in the third photomask M3 may be transferred to a second half field H2, which may correspond to half of the field F. The second half field H2 may be adjacent to the first half field H1 in the y-direction.

The projection optical system included in the photolithography system 1100 may have a reduction rate in the y-direction, e.g., 8:1 that is greater than a reduction rate in the x-direction, e.g., 4:1. The photolithography system 1100 may have a high NA, e.g., 0.55 of each of the second and third photomasks M2 and M3, and thus a critical dimension (CD) of a pattern formed on the wafer WF by the photolithography system 1100 may decrease so as to increase the resolution.

However, when the NA of each of the second and third photomasks M2 and M3 has a high value, the slope angle θ of the light 1700 incident onto each of the second and third photomasks M2 and M3 may increase such that the mask 3D effect may intensify, and such that lights incident onto the second and third photomasks M2 and M3 and lights reflected from the second and third photomasks M2 and M3 may partially overlap each other. Thus, the projection optical system may have a reduction rate in the y-direction that is greater than a reduction rate in the x-direction in order to decrease the slope angle θ of the light 1700 incident onto each of the second and third photomasks M2 and M3.

When the reduction rate in the x-direction is different from the reduction rate in the y-direction in the projection optical system, only a portion of the field F may be covered in a single exposure process using a single photomask. For example, when the exposure process is performed with one shot using a projection optical system having the same reduction rate in the x-direction and in the y-direction, a plurality of exposure processes may be performed using a plurality of photomasks, respectively, to cover the field F entirely. Thus, if a displacement error of a pattern at a boundary between the photomasks occurs, the displacement error needs correcting.

As sizes of patterns that may be formed on a wafer decrease, optical proximity effect (OPE) may occur due to the effect of neighboring patterns during the exposure process, and optical proximity correction (OPC) in which the layout of the patterns are corrected may be performed so as to solve the OPE.

The OPC may be performed at a chip level by the unit of a chip on a wafer, or at a shot level by the unit of a plurality of chips covered by one shot in an exposure equipment. The OPC may be performed by adding a hammer head or a serif to a layout of patterns in order to solve the corner rounding that may occur at a corner of each pattern during the exposure process.

A photomask used in the exposure process may be formed by designing a layout of a pattern to be formed in the photomask, that is, a target pattern, and performing an OPC on the layout of the target pattern. However, a real pattern formed in the photomask may have a placement error with respect to the target pattern, which may be referred to as a photomask registration error, and the displacement error of the photomask also needs correcting.

Accordingly, in order to manufacture a photomask including a pattern having a desired layout, detecting a displacement error between the target pattern having the desired layout and the real pattern formed in the photomask, and feedbacking the displacement error to the layout of the target pattern to correct the layout thereof are needed, and thus, a layout of a final pattern in the photomask may be very similar to the desired layout of the target pattern.

Hereinafter, in consideration of the above-mentioned matters, a method of correcting a displacement error of a pattern of a photomask, a method of manufacturing a photomask using the same, and a method of manufacturing a semiconductor device using the same is described.

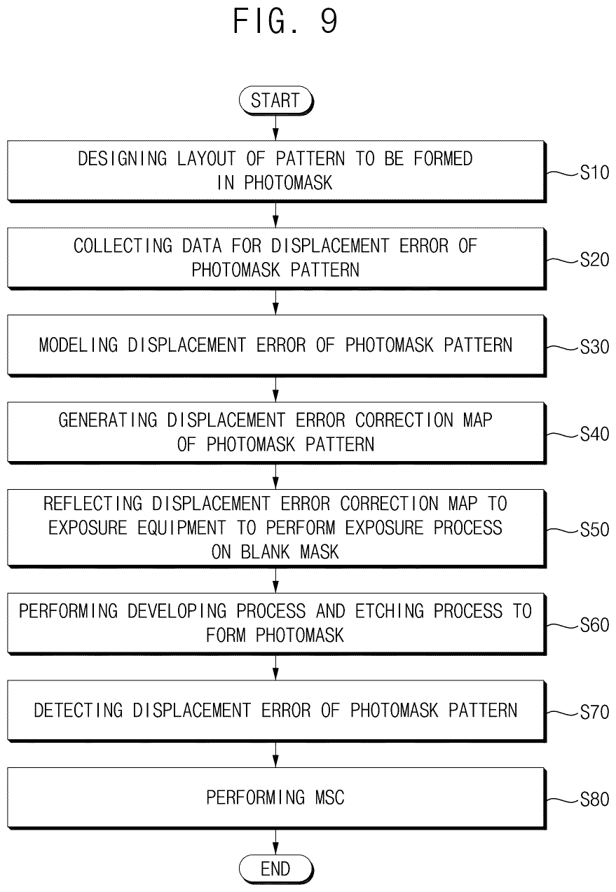

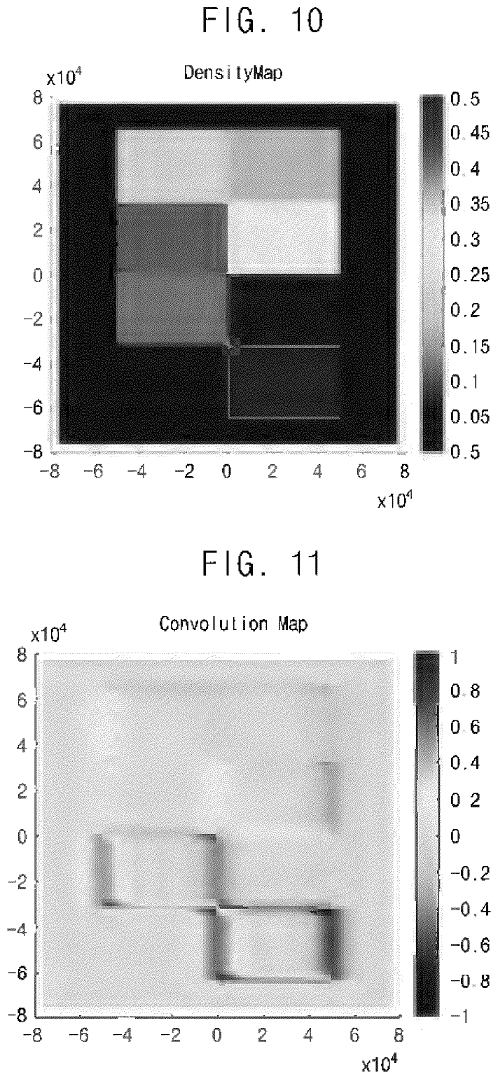

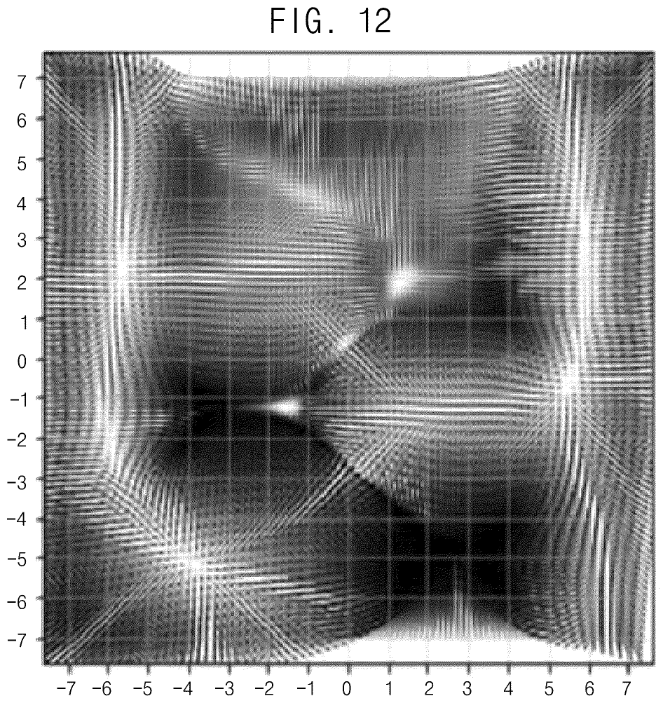

FIG. 9 is a flowchart illustrating a method of correcting a displacement error of a pattern of a photomask and a method of manufacturing a photomask in accordance with example embodiments.

Referring to FIG. 9, in operation S10, a photomask including a pattern having a desired layout may be designed.

That is, a layout of a pattern to be formed in the photomask (hereinafter, referred to as a target pattern) may be designed.

In operation S20, data for correcting a displacement error of the target pattern may be collected.

In example embodiments, the data may include various data of the designed photomask and various data of previously-manufactured photomasks.

In example embodiments, the data may include, e.g., positions, shapes, sizes, numbers, densities, etc., of the target pattern and patterns included in the previously-manufactured photomasks, respectively, (hereinafter, previously-manufactured patterns).

In example embodiments, the data may also include data about a layout of a displacement error detection pattern for detecting displacement errors of the target pattern and the previously-manufactured patterns, e.g., positions, shapes, sizes, numbers, densities, etc., of the displacement error detection pattern.

In example embodiments, the data may also include properties, e.g., materials, flatness properties, etc., of blank masks, that is, a blank mask for forming the designed photomask and blank masks for forming the previously-manufactured photomasks, respectively. For example, the data may include materials of a substrate, a multi-layered structure, a capping layer and absorber in each of the blank masks. Additionally, the data may include a total indicator reading (TIR) about the flatness of each of the blank masks, and high TIR means low flatness of each of the blank masks.

Hereinafter, the data related to the layout of the pattern, the data related to the layout of the displacement error detection pattern, and the data related to the property of the blank mask may be collectively referred to as a stress-caused pattern displacement error related data.

In example embodiments, the stress-caused pattern displacement error related data may be collected from a photomask pattern displacement error correction map generating system.

In operation S30, modeling of a displacement error of the target pattern may be performed using the collected data in operation S20.

In example embodiments, the modeling of the displacement error of the target pattern may be performed based on pattern displacement error data that is accumulated about the previously-manufactured photomasks, which may have a stress-caused pattern displacement error related data the same as, substantially the same as, or similar to that of the designed photomask.

For example, the data collected in operation S20 may be analyzed to classify the previously-manufactured photomasks into a first group of previously-manufactured photomasks having the stress-caused pattern displacement error related data the same as, substantially the same as, or similar to (e.g., matching the displacement error of the designed photomask within a matching criteria threshold level) that of the designed photomask and a second group of previously-manufactured photomasks having the stress-caused pattern displacement error related data different from that of the designed photomask (e.g., a displacement error not matching the displacement error of the designed photomask within the matching criteria threshold level), an error between a position of a real pattern and a position of a target pattern in each previously-manufactured photomask in the first group, that is, a pattern displacement error may be extracted, and the modeling of the displacement error of the target pattern may be performed based on the extracted pattern displacement error.

In an example embodiment, the pattern displacement error data accumulated about the previously-manufactured photomasks may be an average value of the pattern displacement errors of the previously-manufactured photomasks, respectively, which are stored at each position. Alternatively, the pattern displacement error data accumulated about the previously-manufactured photomasks may be an average value of the pattern displacement errors of the previously-manufactured photomasks, respectively, after assigning weights on some of the errors, e.g., recent errors, which are stored at each position.

The modeling of the displacement error of the target pattern may be performed by the photomask pattern displacement error correction map generating system, and the pattern displacement error data accumulated about the previously-manufactured photomasks may be stored in the photomask pattern displacement error correction map generating system.

In an example embodiment, the modeling of the displacement error of the target pattern may be performed based on at least one data included in the stress-caused pattern displacement error related data, and some or all of other data among the stress-caused pattern displacement error related data of the designed photomask may be substantially the same as similar to corresponding ones of the stress-caused pattern displacement error related data of the previously-manufactured photomasks.

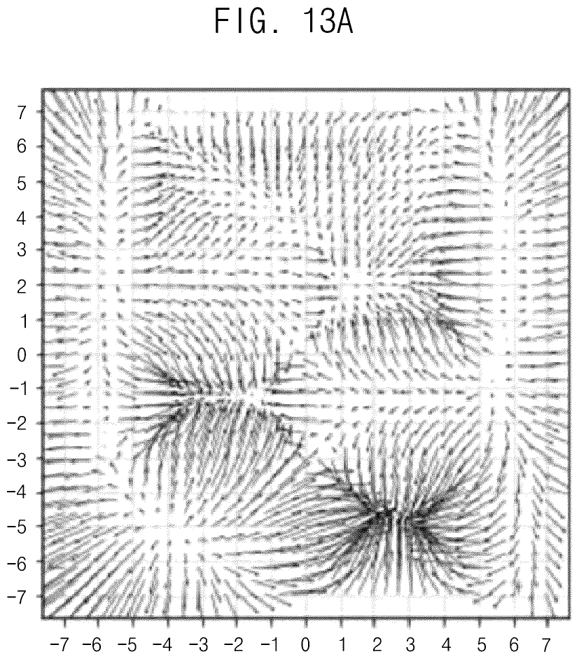

FIG. 10 is a density map of target patterns included in a designed photomask in accordance with example embodiments, and FIG. 11 is a convolution map of position data of the target patterns included in the photomask of FIG. 10 and displacement error data of patterns included in the previously-manufactured photomasks in which the density of the patterns is the same as, substantially the same as, or similar to that of the designed photomask.

In FIG. 10, the designed photomask may include eight regions, and densities of the target patterns in the respective regions may be different from each other. The densities of the target patterns in the regions may be, e.g., 1%, 5%, 11%, 17%, 22%, 28%, 40% and 50%, respectively.

Referring to FIGS. 10 and 11, a large amount of pattern displacement error may occur at positions where the densities of the target patterns change.

If the target patterns included in the designed photomask have different densities depending on regions, the modeling of the pattern displacement error may be performed using convolution of the position data of the target patterns of the designed photomask and the pattern displacement error data of the previously-manufactured photomasks including the patterns that may have a density distribution the same as, substantially the same as, or similar to (e.g., matching within a matching criteria threshold level) that of the designed photomask.

Some or all of other data among the stress-caused pattern displacement error related data, except for the density data, of the designed photomask and may be substantially the same as similar to corresponding ones of the stress-caused pattern displacement error related data of the previously-manufactured photomasks. That is, only some of the previously-manufactured photomasks having the stress-caused pattern displacement error related data the same as, substantially the same as, or similar to that of the designed photomask may be sorted, and a convolution of a pattern position error of the patterns included in the sorted photomasks according to the density thereof and a position of the target pattern in the designed photomask may be performed so that the modeling of the pattern displacement error may be performed.

In operation S40, a displacement error correction map of the target pattern may be generated based on the modeling of the pattern displacement error performed in operation S30.

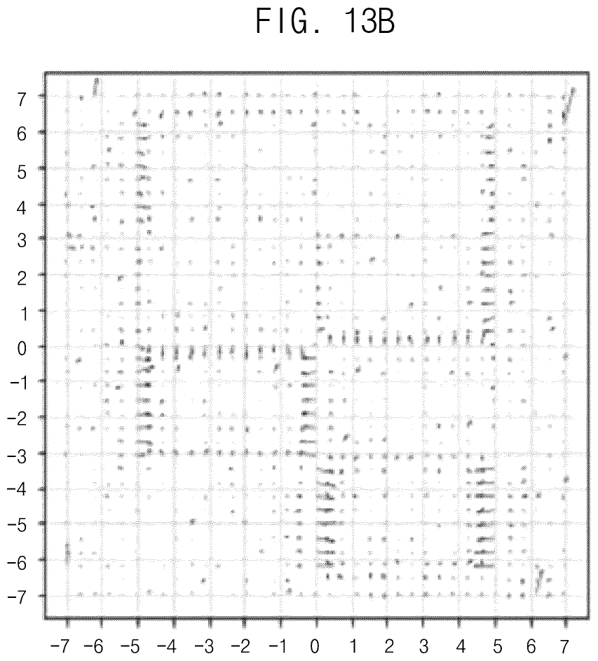

FIG. 12 is a displacement error correction map of the target pattern generated based on the convolution map shown in FIG. 11, FIG. 13A is drawing that shows a displacement error of a real pattern included in the photomask before reflecting the displacement error correction map of the target pattern in an exposure process, and FIG. 13B is drawing that shows a displacement error of the real pattern included in the photomask after reflecting the displacement error correction map of the target pattern in the exposure process.

If a unit of a grid of the error correction map or a layout correction decreases, a correction rate of the pattern displacement error may be enhanced.

Referring to FIGS. 12, 13A and 13B, a displacement error correction map may be generated from the displacement error of the target pattern that may be acquired based on the modeling of the pattern displacement error at each position of the target pattern. The generation of the displacement error correction map of the target pattern may be performed by photomask pattern displacement error correction map generating system.

In operation S50, the displacement error correction map of the target pattern generated in operation S40 may be reflected in an exposure equipment to perform an exposure process.

That is, a photoresist layer may be formed on a blank mask including a multi-layered structure, a capping layer and an absorber sequentially stacked on a substrate, and an exposure process may be performed on the photoresist layer to form a photoresist pattern.

In example embodiments, the exposure process may not be performed according to the layout of the target pattern that is initially designed, but after correcting the layout of the target pattern by reflecting the generated displacement error correction map of the target pattern, and the exposure process may be performed based on the corrected layout of the target pattern. Thus, the exposure process may be performed at positions of the target pattern that are changed from initial positions of the target pattern.

Accordingly, during the exposure process, an electron beam (E-beam) writer for irradiating E-beam onto the photoresist layer may change a direction of irradiating the E-beam through, e.g., a deflector. That is, a bias applied to the deflector by the exposure equipment may be controlled according to the displacement error correction map of the target pattern so that the position of the real pattern that may be formed in the photomask may be corrected. In example embodiments, a magnitude and a direction of the E-beam may be corrected so as to offset the pattern displacement error at each position of the target pattern, and the exposure process may be performed.

Accordingly, the exposure process may be performed, using the pattern displacement error correction map generated in operation S40, so that the position of the real pattern that may be formed in the photomask may be close to the position of the target pattern.

In operation S60, a developing process may be performed on the photoresist layer after the exposure process to form a photoresist pattern, and the absorber in the blank mask may be etched by an etching process using the photoresist pattern as an etching mask, so that the blank mask may be converted into a photomask including a real pattern.

In an example embodiment, before the developing process, a baking process may be further performed on the photoresist layer. The photoresist pattern may be removed by, e.g., an ashing process and/or a stripping process.

In operation S70, a displacement error of the real pattern formed in the photomask may be detected.

In an example embodiment, an error between the position of the target pattern of the initially designed photomask and the position of the real pattern formed in the photomask may be detected, and may be represented by a pattern displacement error vector at each position.

That is, the pattern displacement error vector may be indicated by an arrow at each position, and a magnitude of the pattern displacement error vector may be shown by a length of the arrow and a direction of the pattern displacement error vector, that is, a direction (or a reverse direction) from the position of the target pattern toward a corresponding position of the real pattern may be shown by a direction of the arrow.

In operation S80, a mask spec check (MSC) may be performed on the layout of the real pattern formed in the photomask, and if the MSC is passed, manufacturing the photomask including the real pattern may be completed. However, the MSC is not passed, operations S20 to S70 may be performed again.

In example embodiments, the MSC may include confirming as to whether the magnitude of the detected pattern displacement error is within a reference range, that is, whether the magnitude of the detected pattern displacement error satisfies a desired spec. For example, three times a standard deviation of the pattern displacement errors detected at all positions, respectively, of the designed photomask is equal to or less than about several nanometers in each of the x-direction and the y-direction, then the magnitude of the detected pattern displacement error may be considered to be within the reference range to pass the MSC.

If the MSC is not passed to perform operations S20 to S70 again, data used in operations S20 to S70 for forming the photomask may be added to the data collected in operation S20 as a part of the data about the previously-manufactured photomasks, and thus the modeling of the pattern displacement error and the generation of the pattern displacement error correction map performed in operations S30 and S40, respectively, may be performed more precisely.

In example embodiments, performing operations S20 to S70 again may be repeated until the layout of the real pattern formed in the photomask passes the MSC. When operations S20 to S70 are repeated, another photomask may be formed in operation S60.

As illustrated above, the displacement error between the target pattern of the photomask designed in operation S10 and the real pattern formed in the photomask may be reduced by operations S20 to S80, so that the photomask may be finally manufactured to include the real pattern having a layout very similar to the layout of the target pattern of the initially designed photomask.

That is, the modeling of the displacement error of the target pattern of the initially designed photomask may be performed based on the pattern displacement error of the previously-manufactured photomasks having data the same as, substantially the same as, or similar to at least some of the stress-caused pattern displacement error related data of the initially designed photomask, the displacement error correction map of the target pattern may be generated based on the modeling of the displacement error of the target pattern, and the exposure process may be performed on the blank mask in reflection of the generated displacement error correction map of the target pattern to firstly manufacture the photomask. Thus, the error between the position of the real pattern formed in the photomask and the position of the target pattern in the initially designed photomask may be corrected.

The displacement error of the real pattern of the firstly manufactured photomask may be detected, and if the detected displacement error is within a desired range, the firstly manufactured photomask may be considered as a final photomask and the manufacturing of the photomask may be completed. However, if the detected displacement error is not within the desired range, the above operations may be repeatedly performed, so that the final photomask may be manufactured to include a real pattern having similar layout of the layout of the target pattern.

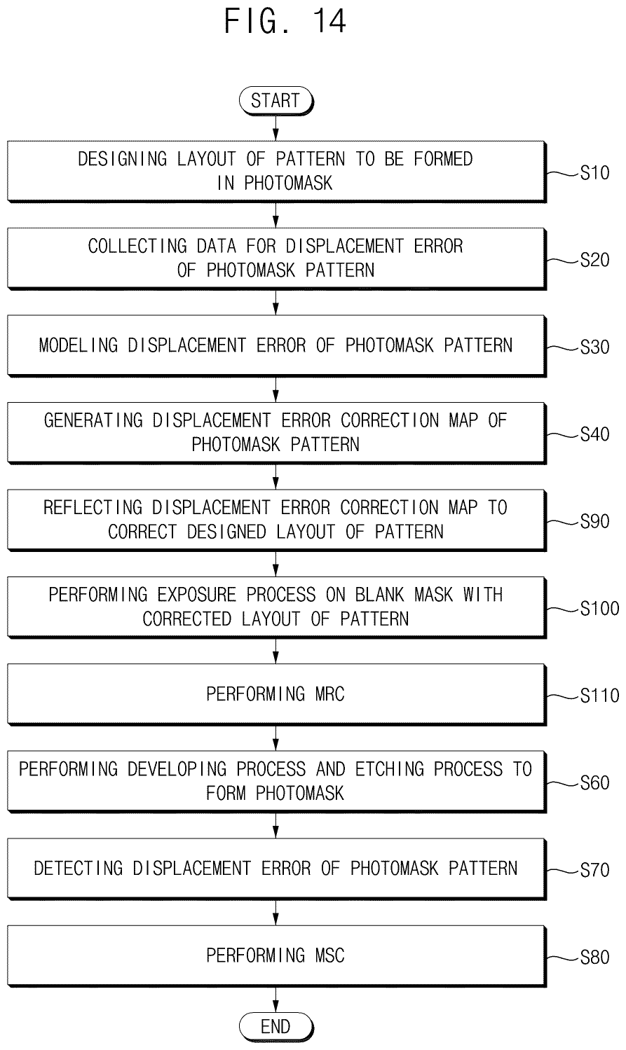

FIG. 14 is a flowchart illustrating a method of correcting a pattern displacement error and a method of manufacturing a photomask in accordance with example embodiments.

This method may include processes the same as, substantially the same as, or similar to those illustrated with reference to FIGS. 9 to 13, and thus repeated explanations are omitted herein.

Referring to FIG. 14, operations S10 to S40 may be performed to generate the displacement error correction map of the target pattern.

In operation S90, the layout of the target pattern designed in operation S10 may be corrected by reflecting the displacement error correction map of the target pattern generated in operation S40.

That is, the layout of the target pattern may be corrected so that each position of the target pattern may move to offset the pattern displacement error. Thus, using the pattern displacement error correction map generated in operation S40, the position of the real pattern that may be formed in the photomask may be corrected to be close to the position of the target pattern.

In operation S100, the exposure process may be performed on the blank mask with the layout of the target pattern corrected by operation S90.

In operation S110, a mask rule check (MRC) may be performed.

Operations S60 to S80 may be performed to complete the manufacturing of the photomask.

As illustrated above, the displacement error between the target pattern of the photomask designed in operation S10 and the real pattern formed in the photomask may be corrected by operations S20 to S40, S90 to S110, and S60 to S80, and thus the final photomask may be manufactured to include the real pattern having the similar layout to the layout of the target pattern.

The layout of the target pattern may be corrected by reflecting the pattern displacement error correction map, and the exposure process may be performed according to the corrected layout of the target pattern. Accordingly, the error between the position of the real pattern formed in the photomask and the position of the target pattern of the initially designed photomask may be corrected.

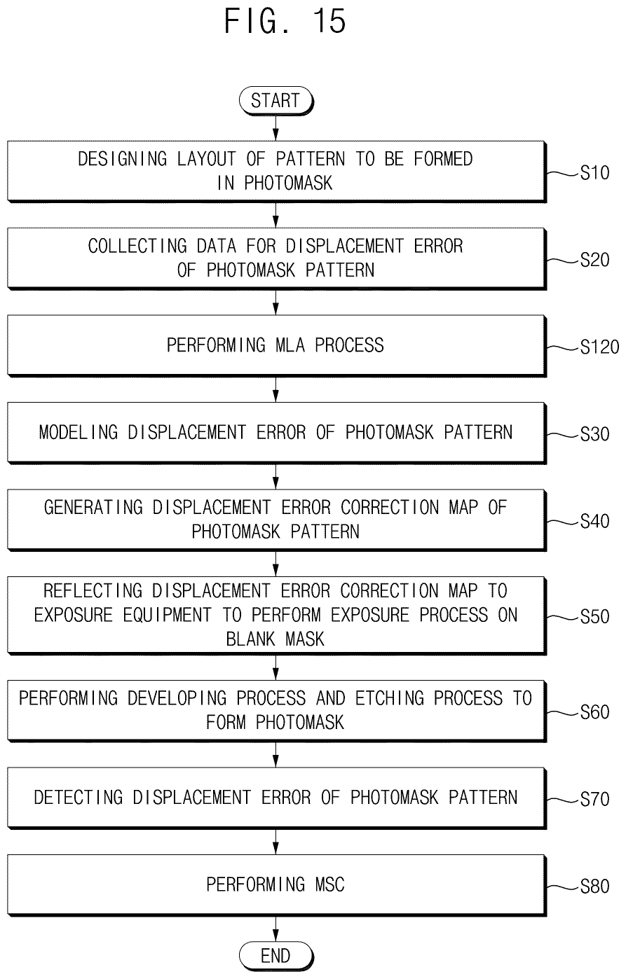

FIG. 15 is a flowchart illustrating a method of correcting a pattern displacement error and a method of manufacturing a photomask in accordance with example embodiments.

This method may include processes the same as, substantially the same as, or similar to those illustrated with reference to FIGS. 9 to 13 or FIG. 14, and thus repeated explanations are omitted herein.

Referring to FIG. 15, operations S10 and S20 may be performed to design the photomask including the target pattern having a desired layout, and data for correcting the displacement error of the target pattern included in the photomask may be collected.

The data may include various data about the designed photomask, and various data accumulated about the previously-manufactured photomasks.

In example embodiments, the data may further include data about the first border region 664 or the first black border 664 illustrated with reference to FIGS. 3 and 4, in addition to the stress-caused pattern displacement error related data.

The data about the first border region 664 or the first black border 664 may include, e.g., a position of the first border region 664 in the photomask, that is, a position of a portion of the multi-layered structure included in the blank mask to which the laser annealing process is performed to form the first border region 664, and hereinafter, may be referred to as a multi-layered structure annealing (MLA) caused pattern displacement error related data.

FIG. 16 is an image of four corners of a region where the MLA process is performed in the blank mask.

Referring to FIG. 16, the MLA process may be performed at a region close to an edge portion of the blank mask.

The MLA-caused pattern displacement error related data may also be collected from the photomask pattern displacement error correction map generating system.

In operation S120, the MLA process may be performed on the multi-layered structure of the blank mask.

As the MLA process is performed, as illustrated with reference to FIGS. 3 and 4, a portion of the multi-layered structure of the blank mask may be crystallized to have a reduced thickness, and the recess 662 may be formed on the blank mask. Thus, the first border region 664 having a relatively low reflectivity may be formed in the blank mask.

As the MLA process is performed, a relative position of each portion of the blank mask may be changed, which may cause a displacement error of a real pattern formed in the photomask.

In operation S30, the modeling of the displacement error of the target pattern may be performed using the data collected in operation S20.

In example embodiments, the modeling of the displacement error of the target pattern may be performed based on pattern displacement error data that is accumulated about the previously-manufactured photomasks, which may have a MLA-caused pattern displacement error related data the same as, substantially the same as, or similar to that of the designed photomask.

In an example embodiment, some or all of the stress-caused pattern displacement error related data, in addition to the MLA-caused pattern displacement error related data, of the designed photomask may be substantially the same as similar to corresponding ones of the stress-caused pattern displacement error related data of the previously-manufactured photomasks.

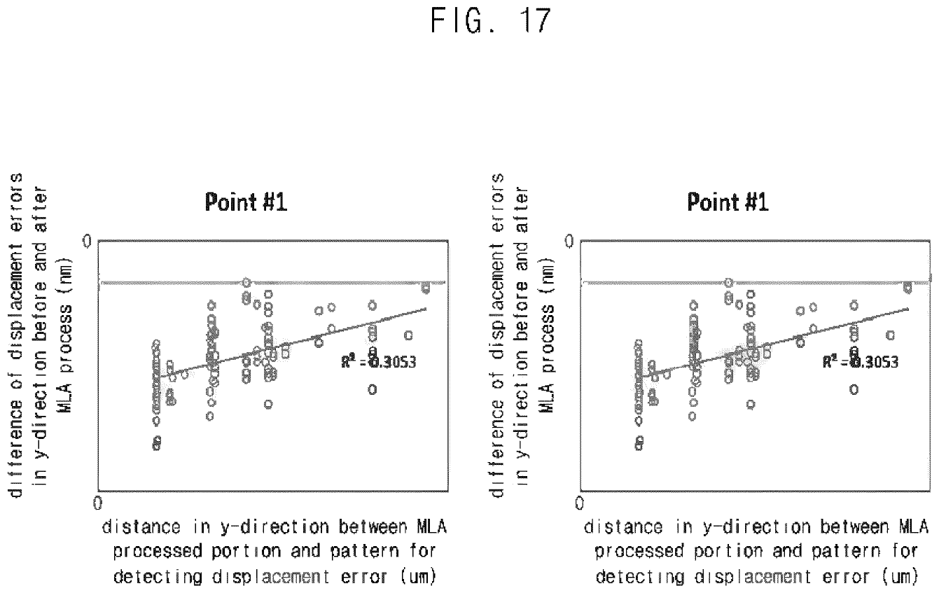

FIG. 17 is a drawing illustrating the modeling of the pattern displacement error performed based on the pattern displacement error of the previously-manufactured photomasks at a region close to first and fourth points P1 and P4 that are located in a region where the MLA process is performed in FIG. 16.

Referring to FIG. 17, as a distance Δx between a position of a portion on which the MLA process is performed and a position of detection decreases, a pattern displacement error (skew) increases, and as the distance Δx between the position of the portion on which the MLA process is performed and the position of detection increases, the pattern displacement error (skew) decreases.

In operation S40, the displacement error correction map of the target pattern may be generated based on the modeling of the pattern displacement error performed in operation S30.

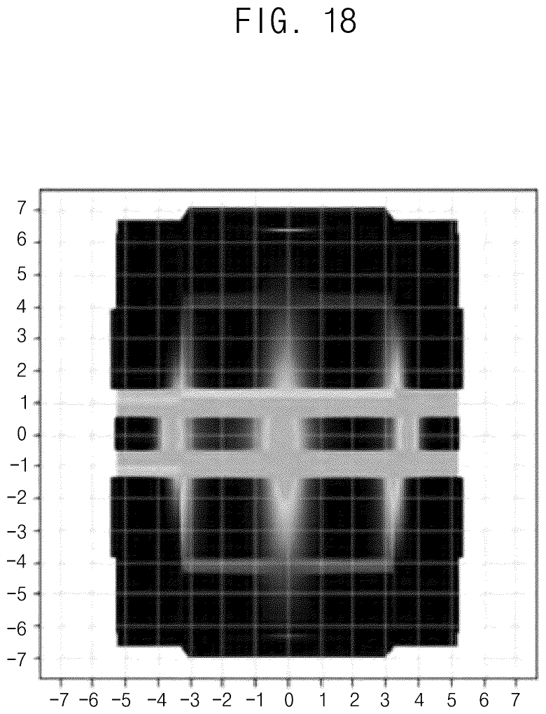

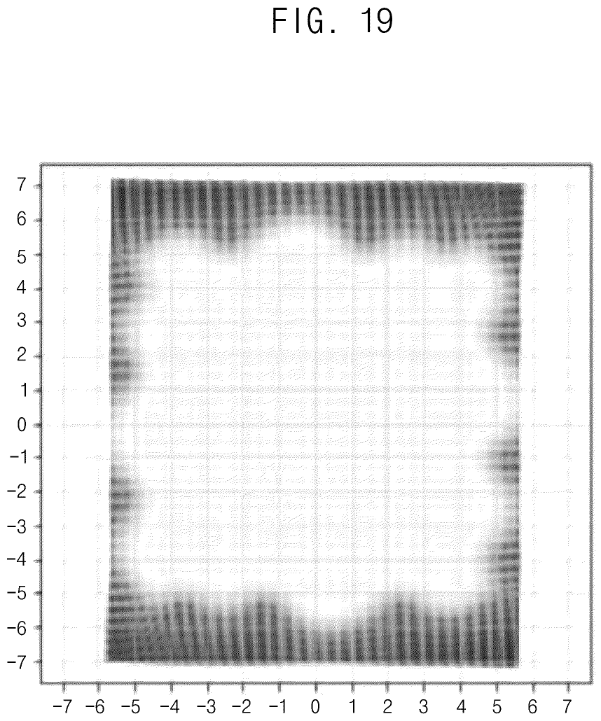

FIGS. 18 and 19 are displacement error correction maps of the target pattern generated based on the modeling of the pattern displacement error in FIG. 17. Particularly, FIG. 17 is a displacement error correction map of the target pattern of a logic device, and FIG. 18 is a displacement error correction map of the target pattern of a DRAM device.

In operation S50, an exposure process may be performed by reflecting the displacement error correction map of the target pattern generated in operation S40 to an exposure equipment.

Operation S60 may be performed to manufacture a photomask, and a pattern displacement error of the photomask may be detected by operation S70.

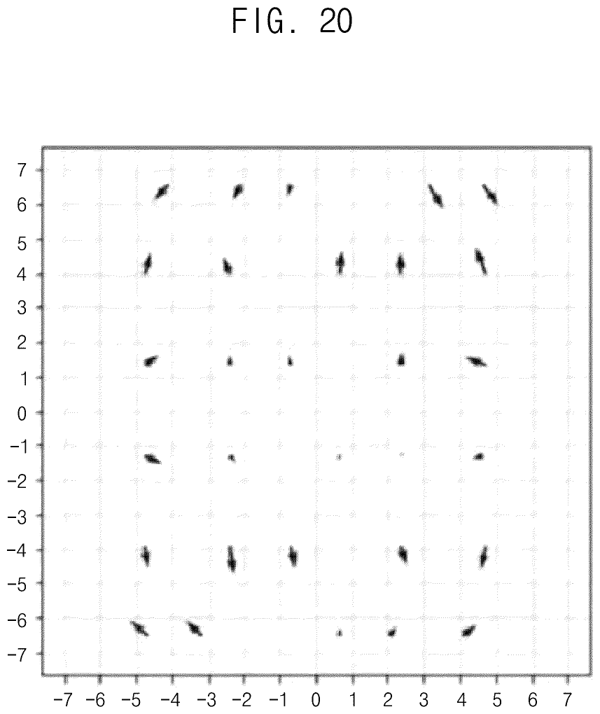

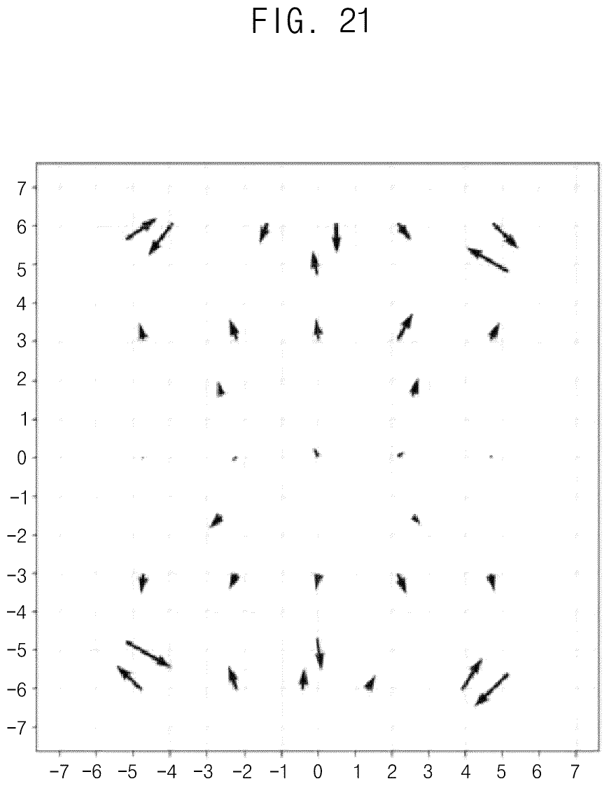

FIGS. 20 and 21 are drawings showing displacement errors of real patterns in the photomasks, respectively, that are manufactured by reflecting the pattern displacement error correction maps shown in FIGS. 18 and 19, respectively.

Referring to FIGS. 20 and 21, error between the position of the target pattern and the position of the real pattern may be detected to be represented by a pattern displacement error vector at each position.

A magnitude of a pattern displacement error vector at an edge portion of the photomask is greater than a magnitude of a pattern displacement error vector at a central portion of the photomask.

Operation S80 may be performed to complete the manufacturing the photomask.

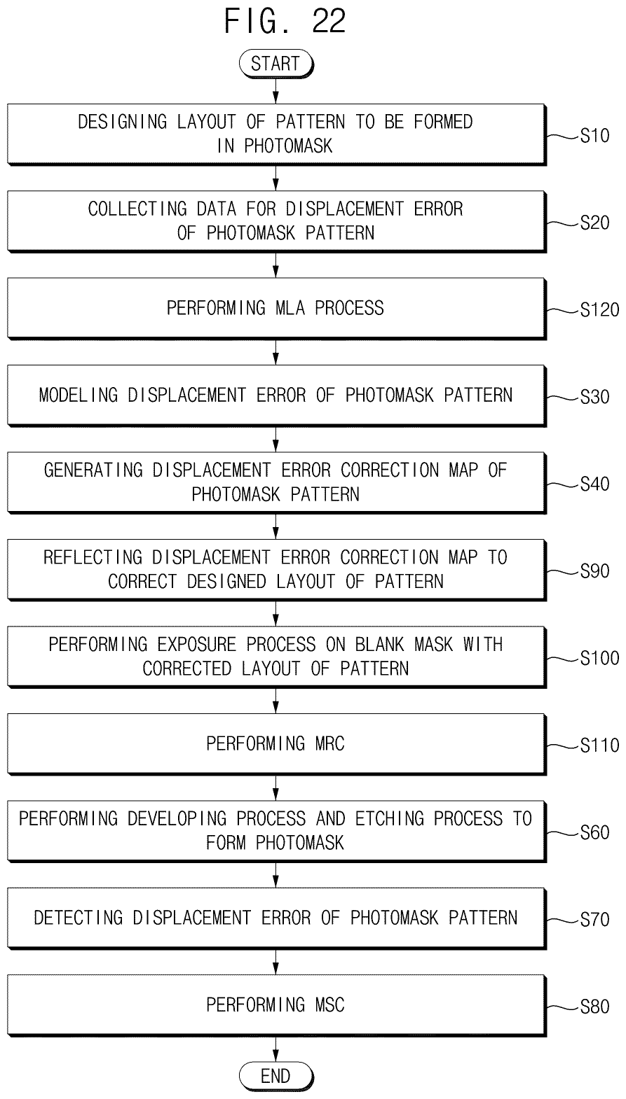

FIG. 22 is a flowchart illustrating a method of correcting a pattern displacement error of a photomask and a method of manufacturing a photomask in accordance with example embodiments.

This method is an application of the method illustrated with reference to FIG. 14 to the method illustrated with reference to FIG. 15, and may include processes the same as, substantially the same as, or similar to those illustrated with reference to FIGS. 14 and 15. Thus, repeated explanations are omitted herein.

Referring to FIG. 22, operations S10 and S20, S120, and S30 and S40 may be performed to generate a pattern displacement error correction map of the target pattern based on the MLA-caused pattern displacement error related data.

Operation S90 may be performed to correct the layout of the target pattern designed in operation S10 in reflection of the displacement error correction map of the target pattern generated in operation S40.

Operation S100 may be performed so that an exposure process may be performed on the blank mask with the corrected layout of the target pattern, and the MRC may be performed in operation S110.

Operations S60 to S80 may be performed to complete the manufacturing the photomask.

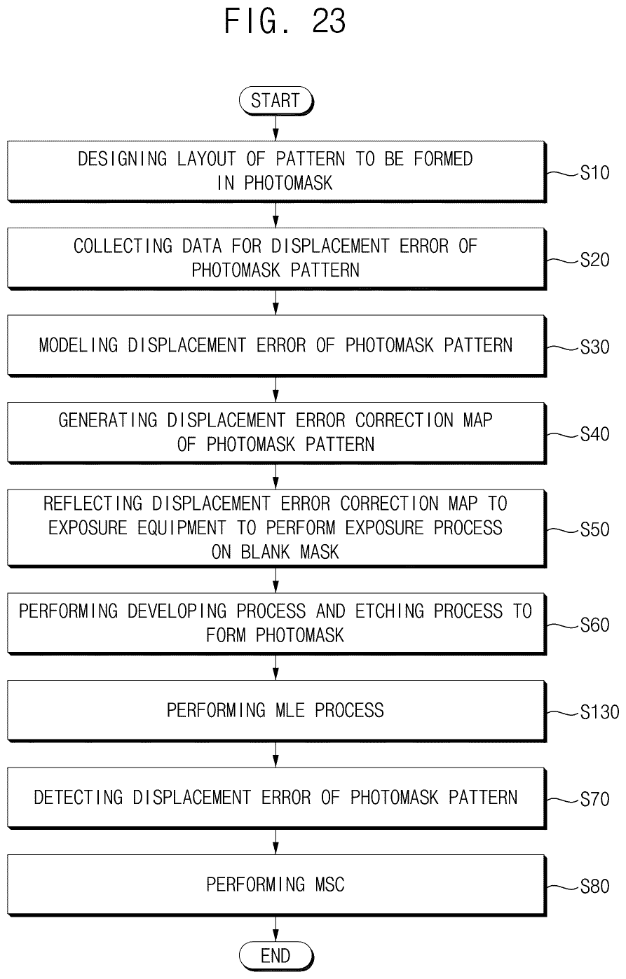

FIG. 23 is a flowchart illustrating a method of correcting a pattern displacement error of a photomask and a method of manufacturing a photomask in accordance with example embodiments.

This method may include processes the same as, substantially the same as, or similar to those illustrated with reference to FIG. 15, and thus repeated explanations are omitted herein.

Referring to FIG. 23, operations S10 and S20 may be performed to design the photomask including the target pattern having a desired layout, and data for correcting the displacement error of the target pattern may be collected.

The data may include various data about the designed photomask and various data about the previously-manufactured photomasks.

In example embodiments, the data may include data about the second border region 668 or the second black border 668 illustrated with reference to FIGS. 5 and 6, in addition to the stress-caused pattern displacement error related data.

The data about the second border region 668 or the second black border 668 may include, e.g., a position of the second border region 668 in the photomask, that is, positions of portions of the multi-layered structure, the capping layer and the absorber included in the blank mask on which the etching process is performed to form the second border region 668, and hereinafter, may be referred to as a multi-layered structure etching (MLE) caused pattern displacement error related data.

The MLE-caused pattern displacement error related data may also be collected from the photomask pattern displacement error correction map generating system.

In operation S30, the modeling of the displacement error of the target pattern may be performed using the data collected in operation S20.

In example embodiments, the modeling of the displacement error of the target pattern may be performed based on pattern displacement error data that is accumulated about the previously-manufactured photomasks, which may have a MLE-caused pattern displacement error related data the same as, substantially the same as, or similar to that of the designed photomask.

In an example embodiment, some or all of the stress-caused pattern displacement error related data, in addition to the MLE-caused pattern displacement error related data, of the designed photomask may be substantially the same as similar to corresponding ones of the stress-caused pattern displacement error related data of the previously-manufactured photomasks.

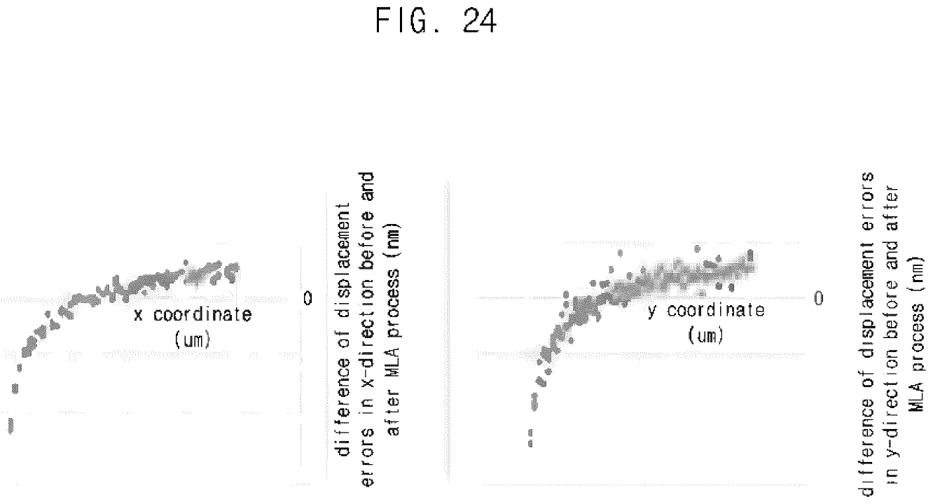

FIG. 24 is drawings illustrating the modeling of pattern displacement error based on the pattern displacement error of the previously-manufactured photomasks in a region where the MLE process is performed.

In the left drawing in FIG. 24, a horizontal axis represents x coordinate of each pattern, and a vertical axis represents a displacement error in the x-direction of each pattern. In the right drawing in FIG. 24, a horizontal axis represents y coordinate of each pattern, and a vertical axis represents a displacement error in the y-direction of each pattern.

Referring to FIG. 24, when the position at which the MLE process is performed is a region extending in the y-direction (the left drawing), as the position approaches the region, a pattern displacement error in the x-direction (dx) increases, while as the position recedes from the region, the pattern displacement error in the x-direction (dx) decreases. Additionally, when the position at which the MLE process is performed is a region extending in the x-direction (the right drawing), as the position approaches the region, a pattern displacement error in the y-direction (dy) increases, while as the position recedes from the region, the pattern displacement error in the y-direction (dy) decreases.

In operation S40 of FIG. 23, the displacement error correction map of the target pattern may be generated based on the modeling of the pattern displacement error performed in operation S30.

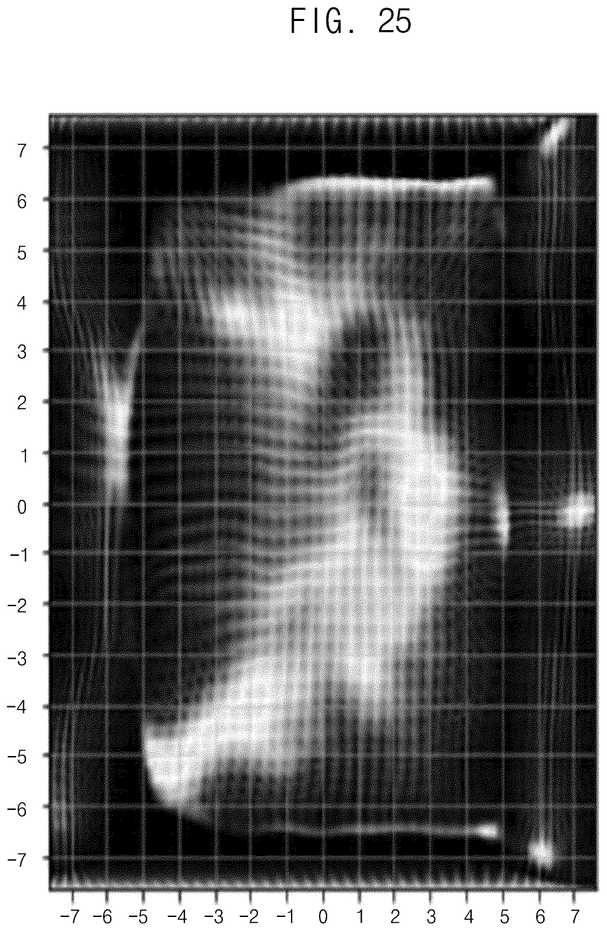

FIG. 25 is a displacement error correction map of the target pattern generated based on the modeling of the pattern displacement error shown in FIG. 24.

Operation S50 of FIG. 23 may be performed so that an exposure process may be performed in reflection of the displacement error correction map of the target pattern to an exposure equipment, and operation S60 may be performed to manufacture a photomask including a real pattern from the blank mask.

In operation S130 of FIG. 23, the MLE process may be performed on the multi-layered structure, the capping layer and the absorber of the photomask.

As the MLE process is performed, as illustrated with reference to FIGS. 5 and 6, a portion of the photomask may be etched to form the opening 666, and the second border region 668 having a relatively low reflectivity may be formed in the photomask.

As the MLE process is performed, a relative position of each portion of the blank mask may be changed, which may cause a displacement error of a real pattern formed in the photomask.

Operation S70 of FIG. 23 may be performed to detect an error between the position of the real pattern of the photomask and the target pattern of the designed photomask.

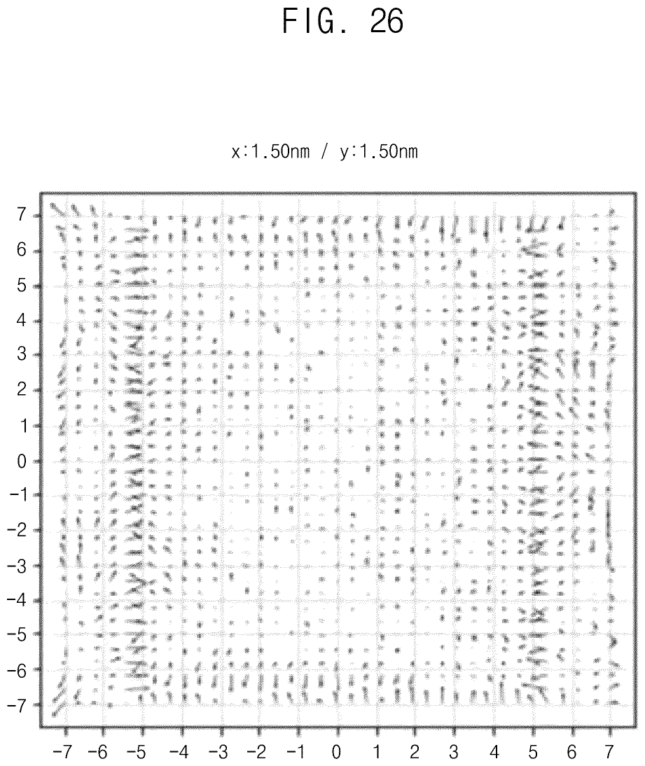

FIG. 26 is a drawing showing the pattern displacement error of the photomask.

Referring to FIG. 26, an error between the position of the target pattern of the initially designed photomask and the position of the real pattern formed in the photomask may be detected, and may be represented by a pattern displacement error vector at each position.

A magnitude of the pattern displacement error vector at an edge portion of the photomask may be greater than a magnitude of the pattern displacement error vector at a central portion of the photomask.

Even though the pattern displacement error occurs due to the position change of the real pattern formed in the photomask by the MLE process, operations S30 to S60 may be performed in consideration of the position change, and thus the error may not be large.

Operations S80 of FIG. 23 may be performed to complete the manufacturing of the photomask.

As illustrated above, after performing operations S10 to S60 of FIG. 0.23, the MLE process may be performed in operation S130, and operations S70 and S80 may be performed to complete the manufacturing of the photomask. However, the inventive concept may not be limited thereto, and for example, the MLE process in operation S130 may be performed between operations S20 and S30 as the MLA process illustrated with reference to FIG. 15.

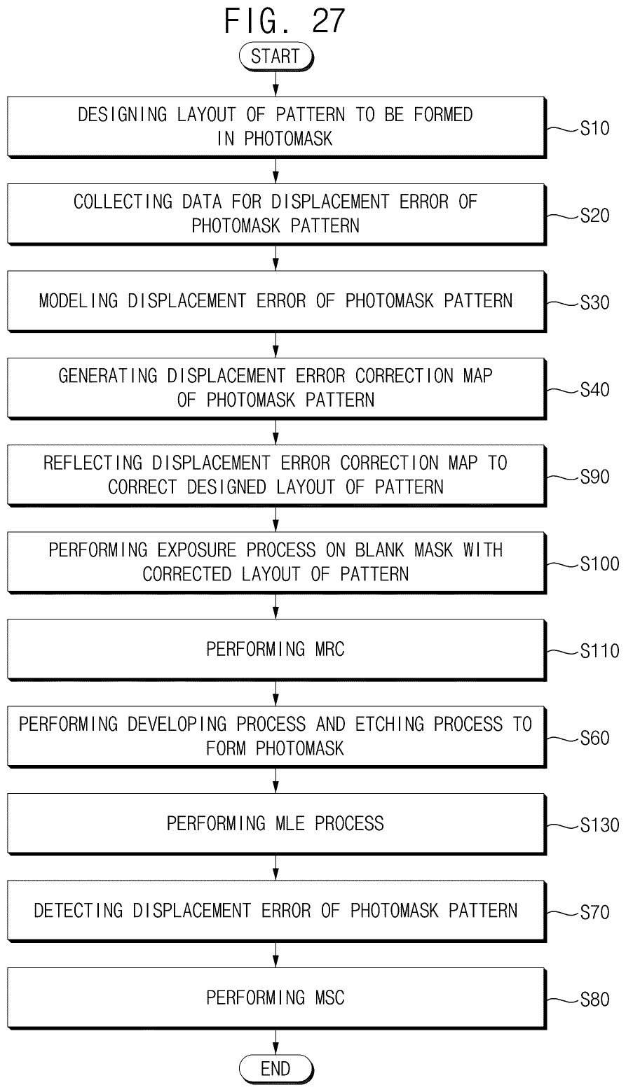

FIG. 27 is a flowchart illustrating a method of correcting a pattern displacement error of a photomask and a method of manufacturing a photomask in accordance with example embodiments.

This method is an application of the method illustrated with reference to FIG. 14 to the method illustrated with reference to FIG. 23, and may include processes the same as, substantially the same as, or similar to those illustrated with reference to FIGS. 14 and 23. Thus, repeated explanations are omitted herein.

Referring to FIG. 27, operations S10 to S40 may be performed to generate the displacement error correction map of the target pattern based on the MLE-caused pattern displacement error related data.

Operation S90 may be performed to correct the layout of the target pattern designed in operation S10 in reflection of the displacement error correction map of the target pattern generated in operation S40.

Operation S100 may be performed so that an exposure process may be performed on the blank mask with the corrected layout of the target pattern, and the MRC may be performed in operation S110.

Operations S60, S130, S70 and S80 may be performed to complete the manufacturing the photomask.

However, the MLE process may be performed between operations S20 and S30, as the method illustrated with reference to FIG. 23.

In example embodiments, one or some of the method illustrated with reference to FIGS. 9 and 14, that is, the method of correcting the pattern displacement error of the photomask using the stress-caused pattern displacement error related data, the method illustrated with reference to FIGS. 15 and 22, that is, the method of correcting the pattern displacement error of the photonmask using the MLA-caused pattern displacement error related data, and the method illustrated with reference to FIGS. 23 and 27, that is, the method of correcting the pattern displacement error of the photomask using the MLE-caused pattern displacement error related data may be performed. Alternatively, the above methods may be independently performed.

The photomask manufactured using the method of correcting the pattern displacement error of the photomask may be used in a photolithography process that may be performed when a semiconductor device is manufactured. That is, in the photolithography process for forming various patterns included in the semiconductor device, a photoresist layer may be formed on an etching object layer on a substrate, an exposure process and a developing process may be performed on the photoresist layer using the manufactured photomask to form a photoresist pattern, and an etching process may be performed on the etching object layer using the photoresist pattern as an etching mask to form a pattern having a desired layout.

The semiconductor device may include logic devices such as CPUs, MPUs, APs, etc., volatile memory devices such as SRAMs, DRAMs, etc., and non-volatile memory devices such as flash memory devices, PRAMs, MRAMs, RRAMs, etc.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been shown and described with reference to example embodiments thereof, it will be understood by those of ordinary skill in the art that various changes in form and details may be made thereto without departing from the spirit and scope of inventive concepts as set forth by the following claims.

1. A method of manufacturing a photomask, the method comprising:
designing a layout of a target pattern to be formed in the photomask;
performing a modeling of a displacement error of the target pattern and generating a displacement error correction map of the target pattern, based on the modeling of the displacement error;
performing an exposure process on a blank mask in reflection of the displacement error correction map of the target pattern; and
performing a developing process and an etching process on the blank mask to form the photomask.

2. The method according to claim 1, further comprising:
prior to the performing the modeling of the displacement error of the target pattern, collecting data about pattern displacement error.

3. The method according to claim 2, wherein
the collecting the data about the pattern displacement error includes collecting data about pattern displacement error of the target pattern and data about pattern displacement error of patterns included in previously-manufactured photomasks.

4. The method according to claim 3, wherein collecting the data about the pattern displacement error includes collecting the data about pattern displacement error from a photomask pattern displacement error correction map generating system.

5. The method according to claim 3, wherein the data about the pattern displacement error includes data about the layout of the target pattern and data about layouts of patterns included in the previously-manufactured photomasks.

6. The method according to claim 5, wherein
the data about the layout of the target pattern includes positions, shapes, sized, numbers or densities of the target pattern and the patterns included in the previously-manufactured photomasks.

7. The method according to claim 3, wherein the data about the pattern displacement error includes data about layouts of error detection patterns for detecting displacement errors of the target pattern and the patterns included in the previously-manufactured photomasks.

8. The method according to claim 7, wherein the data about the layouts of error detection patterns includes positions, shapes, sized, numbers or densities of the error detection patterns.

9. The method according to claim 3, wherein the data about the pattern displacement error includes blank mask property related data of the blank mask and blank masks used for forming the previously-manufactured photomasks.

10. The method according to claim 9, wherein the blank mask property related data includes materials or flatness properties of the blank mask and the blank masks used for forming the previously-manufactured photomasks.

11. The method according to claim 9, wherein
each of the blank mask and the blank masks used for forming the previously-manufactured photomasks includes
a substrate,
a multi-layered structure on the substrate,
a capping layer on the multi-layered structure, and
an absorber on the capping layer, and
materials of the blank mask and materials of the blank masks used for forming the previously-manufactured photomasks include a material of the absorber.

12. The method according to claim 3, wherein the performing the modeling of the displacement error of the target pattern includes:
classifying the previously-manufactured photomasks into a first group of previously-manufactured photomasks including patterns having pattern displacement error similar to the displacement error of the target pattern; and
extracting an error between a position of a real pattern included in each of the first group of the previously-manufactured photomasks and a position of the target pattern included in the photomask to provide an extracted error.

13. The method according to claim 12, wherein
the generating the displacement error correction map of the target pattern includes generating the displacement error correction map of the target pattern at each position based on the extracted error.

14. The method according to claim 1, wherein the performing the modeling of the displacement error of the target pattern includes:
classifying the previously-manufactured photomasks into a first group of previously-manufactured photomasks including patterns having a pattern density distribution similar to a pattern density distribution of target pattern;
extracting an error between a position of a real pattern included in each of the first group of the previously-manufactured photomasks and a position of the target pattern included in the photomask to provide an extracted error; and
performing a convolution of the position of the target pattern and the extracted error.

15. The method according to claim 1, wherein
the performing the exposure process on the blank mask in reflection of the displacement error correction map of the target pattern includes:
performing the exposure process so as to offset an error at each position in the displacement error correction map of the target pattern.

16-17. (canceled)

18. The method according to claim 1, further comprising:
after the forming the photomask,
detecting a detected pattern displacement error based on a comparison of the layout of the target pattern and a layout of a real pattern in the photomask, and
confirming whether the detected pattern displacement error is within a reference range.

19. The method according to claim 18, further comprising:
classifying the photomask as a final photomask if the detected pattern displacement error is within the reference range.

20. The method according to claim 18, further comprising:
in response to the detected pattern displacement error not being within the reference range, forming another photomask by performing again
the performing the modeling of the displacement error of the target pattern and the generating the displacement error correction map of the target pattern, based on the modeling of the displacement error,
the performing the exposure process on the blank mask in reflection of the displacement error correction map of the target pattern, and
the performing the developing process and the etching process on the blank mask to form the photomask.

21. A method of manufacturing a photomask, the method comprising:
designing a layout of a target pattern to be formed in the photomask;
performing a modeling of a displacement error of the target pattern and generating a displacement error correction map of the target pattern, based on the modeling of the displacement error;
correcting the layout of the target pattern by reflecting the displacement error correction map of the target pattern to provide a corrected layout of the target pattern;
performing an exposure process on a blank mask according to the corrected layout of the target pattern; and
performing a developing process and an etching process on the blank mask to form the photomask.

22-31. (canceled)

32. A method of manufacturing a photomask, the method comprising:
designing a layout of a target pattern to be formed in the photomask;
performing a laser annealing process on a portion of a blank mask to form a border region;
performing a modeling of a displacement error of the target pattern and generating a displacement error correction map of the target pattern, based on the modeling of the displacement error;
performing an exposure process on the blank mask in reflection of the displacement error correction map of the target pattern; and
performing a developing process and an etching process on the blank mask to form the photomask.

33-80. (canceled)
